(19) United States
(12) Patent Application Publication
(10) Pub. No.: US 2022/0076750 A1
(43) Pub. Date: Mar. 10, 2022

(54) MEMORY DEVICE AND METHOD OF OPERATING MEMORY DEVICE

(71) Applicant: SK hynix Inc., Icheon-si Gyeonggi-do (KR)

(72) Inventors: Seong Ju PARK, Icheon-si Gyeonggi-do (KR); Keun Woo LEE, Icheon-si Gyeonggi-do (KR); In Geun LIM, Icheon-si Gyeonggi-do (KR)

(73) Assignee: SK hynix Inc., Icheon-si Gyeonggi-do (KR)

(21) Appl. No.: 17/199,034

(22) Filed: Mar. 11, 2021

(30) Foreign Application Priority Data
Sep. 9, 2020 (KR) 10-2020-0115683

(51) Int. Cl. G11C 16/04; G11C 16/14

(52) U.S. Cl. CPC G11C 16/0483; G11C 11/5635; G11C 16/14

(57) ABSTRACT

A memory device according to an embodiment of the present disclosure may include a string including a plurality of memory cells and a select transistor connected between a conductive line and the plurality of memory cells; a peripheral circuit configured to perform an erase operation of the string; and a control logic configured to control the peripheral circuit to increase a voltage level of an erase voltage applied to the conductive line for a first time period from time one to later time two at a first voltage-time slope, and increase the voltage level of the erase voltage for a second time period from time two to later time three at a second voltage-time slope, during the erase operation, wherein the second voltage-time slope is greater than the first voltage-time slope.

### CROSS-REFERENCE TO RELATED APPLICATION

The present application claims priority under 35 U.S.C. § 119(a) to Korean patent application number 10-2020-0115683, filed on Sep. 9, 2020, in the Korean Intellectual Property Office, the entire disclosure of which is incorporated herein by reference.

### BACKGROUND

### 1. Technical Field

The present disclosure relates to an electronic device, and more particularly, to a memory device and a method of operating the memory device.

### 2. Related Art

A storage device is a device that stores data under control of a host device such as a computer or a smartphone. The storage device may include a memory device in which data is stored and a memory controller controlling the memory device. The memory device may be a volatile memory device or a non-volatile memory device.

The volatile memory device is a device that stores data only when power is supplied and loses the stored data when the power supply is cut off. The volatile memory device may include a static random access memory (SRAM), a dynamic random access memory (DRAM), and the like.

The non-volatile memory device is a device that does not lose data even though power is cut off. The non-volatile memory device may include a read only memory (ROM), a programmable ROM (PROM), an electrically programmable ROM (EPROM), an electrically erasable and programmable ROM (EEPROM), a flash memory, and the like.

### SUMMARY

Embodiments of the present disclosure provide a memory device and a method of operating the memory device capable of improving a characteristic reduction of a select transistor and a memory cell.

A memory device according to an embodiment of the present disclosure may include: a string including a plurality of memory cells and a select transistor connected between a conductive line and the plurality of memory cells; a peripheral circuit configured to perform an erase operation of the string; and a control logic configured to control the peripheral circuit to increase a voltage level of an erase voltage applied to the conductive line for a first time period that includes time one to later time two, maintain the voltage level applied as the erase voltage for a second time period that includes time two to later time three, increase the voltage level of the erase voltage applied for a third time period that includes time three to later time four, and float a select line connected to the select transistor for a fourth time period located between time one and later time two, or for a fifth time period located between time three and later time four, during the erase operation.

A memory device according to an embodiment of the present disclosure may include: a string including a plurality of memory cells and a select transistor connected between a conductive line and the plurality of memory cells; a peripheral circuit configured to perform an erase operation of the string; and a control logic configured to control the peripheral circuit to increase a voltage level of an erase voltage applied to the conductive line for a first time period from time one to later time two at a first voltage-time slope, and increase the voltage level of the erase voltage for a second time period from time two to later time three at a second voltage-time slope, during the erase operation, wherein the second voltage-time slope is greater than the first voltage-time slope.

A memory device according to an embodiment of the present disclosure may include: a string including a plurality of memory cells and a select transistor connected between a conductive line and the plurality of memory cells, a peripheral circuit configured to perform an erase operation of the string; and a control logic configured to control the peripheral circuit to increase a voltage level of an erase voltage applied to the conductive line for a first time period for a time one to a later time two at a first voltage-time slope, increase the voltage level of the erase voltage for a second time period from time two to a later time three at a second voltage-time slope, and increase the voltage level of the erase voltage from the time three to later time four at a third voltage-time slope, during the erase operation, wherein each of the first voltage-time slope and the third voltage-time slope is greater than the second voltage-time slope.

A method of operating a memory device according to an embodiment of the present disclosure may include increasing a voltage level of an erase voltage applied to a conductive line from a first time point to a second time point later than the first time point, maintaining the voltage level of the erase voltage applied to the conductive line from the second time point to a third time point later than the second time point, increasing the voltage level of the erase voltage applied to the conductive line from the third time point to a fourth time point later than the third time point, and floating a select line connected to the select transistor at a fifth time point later than the first time point and earlier than the second time point, or a sixth time point later than the third time point and earlier than the fourth time point.

A method of operating a memory device according to an embodiment of the present disclosure may include increasing a voltage level of an erase voltage applied to a conductive line from a first time point to a second time point later than the first time point at a first slope, and increasing the voltage level of the erase voltage applied to the conductive line from the second time point to a third time point later than the second time point at a second slope, and the second slope may be greater than the first slope.

A method of operating a memory device according to an embodiment of the present disclosure may include increasing a voltage level of an erase voltage applied to a conductive line from a first time point to a second time point later than the first time point at a first slope, increasing the voltage level of the erase voltage applied to the conductive line from the second time point to a third time point later than the second time point at a second slope, and increasing the voltage level of the erase voltage applied to the conductive line from the third point to a fourth point later than the third point at a third slope, and each of the first slope and the third slope may be greater than the second slope.

The present technology provides a memory device capable of improving a characteristic reduction of a select transistor and a memory cell.

### BRIEF DESCRIPTION OF THE DRAWINGS

FIG. 1 is a block diagram illustrating a configuration of a storage device according to an embodiment of the present disclosure.

FIG. 2 is a block diagram illustrating a structure of a memory device of FIG. 1.

FIG. 3 is a block diagram illustrating a structure of a control logic of FIG. 2.

FIG. 4 is a diagram illustrating a structure of any one of memory blocks of FIG. 2.

FIG. 5 is a set of diagrams illustrating an erase operation of a memory device according to embodiments of the present disclosure.

FIG. 6 is a set of diagrams illustrating an erase operation of a memory device according to embodiments of the present disclosure.

FIG. 7 is a set of diagrams illustrating an erase operation of a memory device according to embodiments of the present disclosure.

FIG. 8 is a set of diagrams illustrating an erase operation of a memory device according to embodiments of the present disclosure.

FIG. 9 is a set of diagrams illustrating an erase operation of a memory device according to embodiments of the present disclosure.

FIG. 10 is a set of diagrams illustrating an erase operation of a memory device according to embodiments of the present disclosure.

FIG. 11 is a block diagram illustrating a memory card system to which the storage device may be applied according to an embodiment of the present disclosure.

FIG. 12 is a block diagram illustrating a solid state drive (SSD) system to which the storage device may be applied according to an embodiment of the present disclosure.

FIG. 13 is a block diagram illustrating a user system to which the storage device may be applied according to an embodiment of the present disclosure.

### DETAILED DESCRIPTION

Specific structural or functional descriptions of embodiments according to the concepts which are disclosed in the present specification or application are illustrated only to describe the embodiments according to the concept of the present disclosure. The embodiments according to the concepts of the present disclosure may be carried out in various forms and the descriptions are not limited to the embodiments described in the present specification or application.

Hereinafter, an embodiment of the present disclosure will be described with reference to the accompanying drawings so that those skilled in the art may easily implement the technical spirit of the present disclosure.

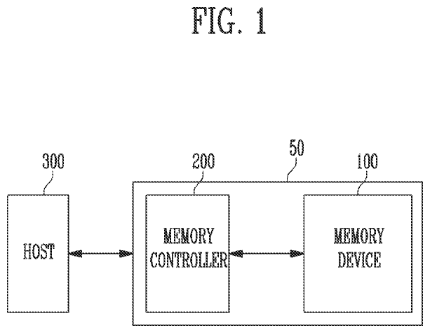

FIG. 1 is a block diagram illustrating a configuration of a storage device according to an embodiment of the present disclosure.

Referring to FIG. 1, the storage device 50 may include a memory device 100 and a memory controller 200. The storage device 50 may be a device that stores data under control of a host 300 such as a cellular phone, a smartphone, an MP3 player, a laptop computer, a desktop computer, a game player, a TV, a tablet PC, or an in-vehicle infotainment system.

The storage device 50 may be manufactured as one of various types of storage devices according to a host interface that is a communication method with the host 300. For example, the storage device 50 may be configured as any one of various types of storage devices such as an SSD, a multimedia card in a form of an MMC, an eMMC, an RS-MMC and a micro-MMC, a secure digital card in a form of an SD, a mini-SD and a micro-SD, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, and a memory stick.

The storage device 50 may be manufactured as any one of various types of packages. For example, the storage device 50 may be manufactured as any one of various types of package types, such as a package on package (POP), a system in package (SIP), a system on chip (SOC), a multi-chip package (MCP), a chip on board (COB), a wafer-level fabricated package (WFP), and a wafer-level stack package (WSP).

The memory device 100 may store data. The memory device 100 operates under control of the memory controller 200. The memory device 100 may include a plurality of planes. The plane may be a region that may independently operate. Each plane may independently perform any one of a program operation, a read operation, and an erase operation.

The memory device 100 may include a memory cell array that includes a plurality of memory cells that store data. The memory cell array may include a plurality of memory blocks. The memory block may include a plurality of memory cells. The memory block may be a unit that performs the erase operation of erasing data stored in the memory device 100. That is, data stored in the same memory block may be simultaneously erased. In an embodiment, the memory block may include a plurality of pages. The page may be a unit for storing data in the memory device 100 or reading data stored in the memory device 100. That is, a physical address provided from the memory controller 200 to the memory device 100 during the program operation or the read operation may be an address for identifying a specific page.

In an embodiment, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory, a resistive random access memory (RRAM), a phase-change random access memory (PRAM), a magnetoresistive random access memory (MRAM), a ferroelectric random access memory (FRAM), a spin transfer torque random access memory (STT-RAM), or the like. In the present specification, for convenience of description, it is assumed that the memory device 100 is a NAND flash memory.

In an embodiment, the memory device 100 may be implemented in a three-dimensional array structure. The present disclosure may be applied not only to a flash memory device in which a charge storage layer consists of a conductive floating gate (FG), but also to a charge trap flash (CTF) in which the charge storage layer consists of an insulating film.

In an embodiment, each of the memory cells included in the memory device 100 may be programmed as one of a single level cell (SLC) that stores one data bit, a multi-level cell (MLC) that stores two data bits, a triple level cell (TLC) that stores three data bits, or a quad level cell (QLC) that stores four data bits.

The memory controller 200 may control an overall operation of the storage device 50. When power is applied to the storage device 50, the memory controller 200 may execute firmware (FW). When the memory device 100 is a flash memory device, the memory controller 200 may execute firmware such as a flash translation layer (FTL) for controlling communication between the host 300 and the memory device 100.

When a write request is input from the host 300, the memory controller 200 may receive a write data to be stored in the memory device 100 and a logical address (LA) for identifying corresponding write data from the host 300. The memory controller 200 may convert the input LA to a physical address (PA) indicating a physical address of memory cells in which the write data is stored among memory cells of the memory device 100. In an embodiment, one PA may correspond to one physical page. The memory controller 200 may provide a program command, the physical address, and the write data for storing data to the memory device 100.

In an embodiment, when a read request is input from the host 300, the memory controller 200 may receive a logical address corresponding to the read request from the host 300. Here, the LA corresponding to the read request may be a LA identifying read requested data. The memory controller 200 may obtain a PA mapped to the LA corresponding to the read request from map data indicating a correspondence relationship between the LA provided by the host 300 and the PA of the memory device 100.

In an embodiment, the memory controller 200 may control the memory device 100 to independently perform the program operation, the read operation, or the erase operation regardless of a request from the host 300. For example, the memory controller 200 may control the memory device 100 to perform background operations such as wear leveling, garbage collection, or read reclaim.

The host 300 may communicate with the storage device 50 using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a universal flash storage (UFS), a secure digital card (SD), a multi-media card (MMC), an embedded MMC (eMMC), a dual in-line memory module (DIMM), a registered DIMM (RDIMM), and a load reduced DIMM (LRDIMM).

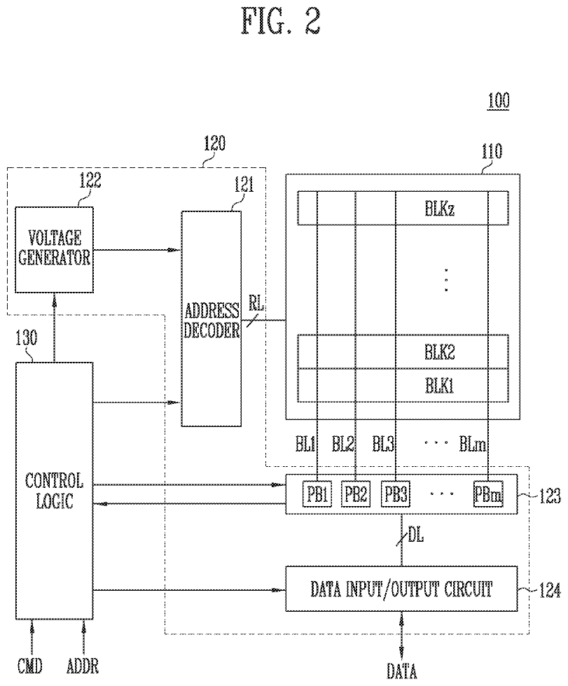

FIG. 2 is a block diagram illustrating an embodiment of the memory device 100 of FIG. 1.

Referring to FIG. 2, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz are connected to an address decoder 121 through row lines RL and connected to a read and write circuit 123 through bit lines BL1 to BLm. The plurality of memory blocks BLK1 to BLKz are commonly connected to the first to m-th bit lines BL1 to BLm. Each of the plurality of memory blocks BLK1 to BLKz may include a plurality of memory cells.

In an embodiment, the plurality of memory cells may be non-volatile memory cells. The row lines RL may include at least one source select line, a plurality of word lines, and at least one drain select line. Memory cells connected to the same word line may be defined as one page. Therefore, one memory block may include a plurality of pages.

Each of the memory cells included in the memory cell array 110 may be configured as a single level cell (SLC) that stores one data bit, a multi-level cell (MLC) that stores two data bits, a triple level cell (TLC) that stores three data bits, or a quad level cell (QLC) that stores four data bits.

The peripheral circuit 120 may be configured to perform the program operation, the read operation, or the erase operation on a selected region of the memory cell array 110 under control of the control logic 130. The peripheral circuit 120 may drive the memory cell array 110. For example, the peripheral circuit 120 may apply various operation voltages to the row lines RL and the first to m-th bit lines BL1 to BLm or discharge the applied voltages under the control of the control logic 130.

The peripheral circuit 120 may include the address decoder 121, a voltage generator 122, the read and write circuit 123, and a data input/output circuit 124.

The address decoder 121 may be connected to the memory cell array 110 through the row lines RL. The control logic 130 may operate the address decoder 121. The address decoder 121 may receive an address from the control logic 130. In an embodiment, the address decoder 121 may decode a block address among the received addresses, and may select any one of the plurality of memory blocks BLK1 to BLKz according to the decoded address. In an embodiment, the address decoder 121 may decode a row address among the received addresses and select any one word line among the selected memory blocks.

The address decoder 121 may select row lines RL corresponding to the selected memory block, and transfer the operation voltages generated by the voltage generator 122 to the selected row lines RL.

Specifically, during the program operation, the address decoder 121 may apply a program voltage to a selected word line and apply a program pass voltage of a level lower than the program voltage to an unselected word line. During a program verify operation, the address decoder 121 may apply a verify voltage to the selected word line and a verify pass voltage higher than the verify voltage to the unselected word line. During the read operation, the address decoder 121 may apply a read voltage to the selected word line and apply a read pass voltage higher than the read voltage to the unselected word line.

In an embodiment, the erase operation of the memory device 100 may be performed in a memory block unit. During the erase operation, the address decoder 121 may select one memory block according to the decoded address. During the erase operation, the address decoder 121 may apply a ground voltage to the word lines connected to the selected memory block.

In an embodiment, the address decoder 121 may further include an address buffer, a block decoder, a row decoder, and the like.

The voltage generator 122 may generate a plurality of voltages using an external power voltage supplied to the memory device 100. The voltage generator 122 may operate in response to control of the control logic 130. For example, the voltage generator 122 may regulate the external power voltage to generate an internal power voltage. The internal power voltage generated by the voltage generator 122 may be provided to the address decoder 121, the read and write circuit 123, the data input/output circuit 124, and the control logic 130, and may be used as an operation voltage of the memory device 100.

For example, the voltage generator 122 may generate a program voltage, a verify voltage, a program pass voltage, a verify pass voltage, a read voltage, an erase voltage, and the like under the control of the control logic 130.

In an embodiment, the voltage generator 122 may include a plurality of pumping capacitors to generate a plurality of operation voltages having various voltage levels. The voltage generator 122 may generate the plurality of operation voltages by selectively activating the plurality of pumping capacitors in response to control of the control logic 130. The generated plurality of operation voltages may be provided to the memory cell array 110 by the address decoder 121.

The read and write circuit 123 may include first to m-th page buffers PB1 to PBm. The first to m-th page buffers PB1 to PBm may be connected to the memory cell array 110 through the first to m-th bit lines BL1 to BLm, respectively. The first to m-th page buffers PB1 to PBm may operate in response to control of the control logic 130. For example, the first to m-th page buffers PB1 to PBm may operate in response to page buffer control signals (not shown).

In an embodiment, the first to m-th page buffers PB1 to PBm may sense data stored in the memory cell array 110 by sensing a voltage or a current of the first to m-th bit lines BL1 to BLm. The first to m-th page buffers PB1 to PBm may temporarily store the sensed data. The first to m-th page buffers PB1 to PBm may provide the sensed data to the data input/output circuit 124 through data lines DL.

In an embodiment, the first to m-th page buffers PB1 to PBm may receive the data to be stored in the memory cell array 110 through the data lines DL from the data input/output circuit 124. The data received by the first to m-th page buffers PB1 to PBm through performance of the program operation may be stored in the memory cell array 110.

The program operation of storing the data in the memory cell may include a program voltage apply step and a verify step. In the program voltage apply step, while the program voltage is applied to the selected word line, the first to m-th page buffers PB1 to PBm may transfer the data to be stored to selected memory cells. A threshold voltage of the memory cell connected to the bit line to which a program permit voltage (for example, a ground voltage) is applied may increase. The threshold voltage of the memory cell connected to the bit line to which a program inhibit voltage (for example, a power voltage) is applied may be maintained. In the verify step of verifying the program operation, the first to m-th page buffers PB1 to PBm may sense the data stored in the memory cells through the first to m-th bit lines BL1 to BLm from the selected memory cells.

The data input/output circuit 124 may be connected to the first to m-th page buffers PB1 to PBm through the data lines DL. The data input/output circuit 124 may operate in response to control of the control logic 130.

The data input/output circuit 124 may provide data DATA received from the memory controller 200 of FIG. 1 to the read and write circuit 123.

In an embodiment, the data input/output circuit 124 may include a plurality of input/output buffers (not shown) that receive the data DATA. During the program operation, the data input/output circuit 124 receives the data DATA, which is to be stored, from the memory controller 200. During the read operation, the data input/output circuit 124 may output the data, which is transferred to the memory controller 200 from the first to m-th page buffers PB1 to PBm included in the read and write circuit 123.

The control logic 130 is configured to control an overall operation of the memory device 100. The control logic 130 may receive a command CMD and an address ADDR.

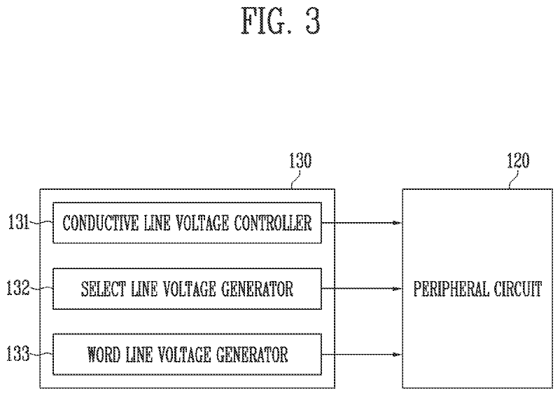

FIG. 3 is a block diagram illustrating an embodiment of the control logic of FIG. 2.

Referring to FIG. 3, the control logic 130 may include a conductive line voltage controller 131, a select line voltage controller 132, and a word line voltage controller 133.

The conductive line voltage controller 131 may generate control signals for controlling a voltage applied to a conductive line during the erase operation and may provide the control signals to the peripheral circuit 120. The conductive line may be a source line or a bit line.

The select line voltage controller 132 may generate control signals for controlling a voltage applied to a select line during the erase operation and may provide the control signals to the peripheral circuit 120. The select line may be the source select line or the drain select line.

The word line voltage controller 133 may generate control signals for controlling a voltage applied to the word line during the erase operation and may provide the control signals to the peripheral circuit 120.

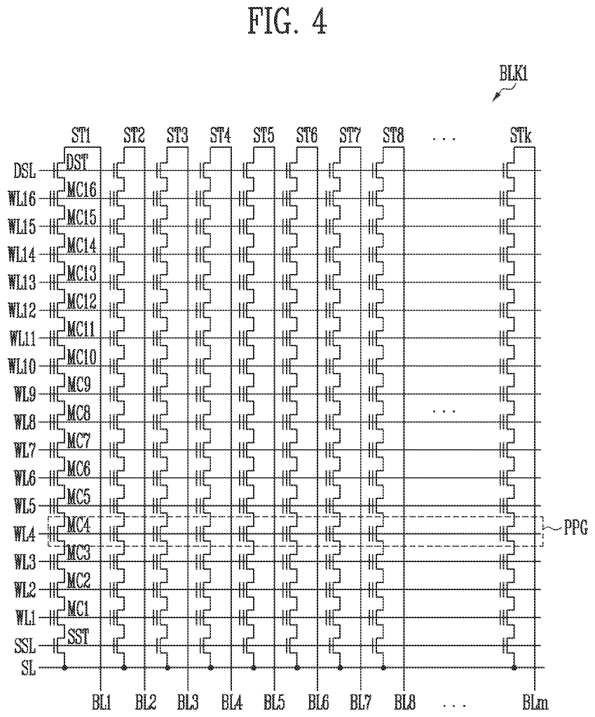

FIG. 4 is a diagram illustrating an embodiment of any one of the memory blocks of FIG. 2.

Referring to FIG. 4, the memory block BLK1 may include a plurality of memory cells respectively connected to a plurality of word lines WL1 to WL16, which are arranged in parallel to each other between a source select line SSL and a drain select line DSL. More specifically, the memory block BLK1 may include a plurality of strings ST1 to STk connected between bit lines BL1 to BLn and a source line SL. The bit lines BL1 to BLn of FIG. 4 may be the first to m-th bit lines BL1 to BLm of FIG. 2.

In an embodiment, as shown, one of the strings ST1 to STk may be connected to one of the bit lines BL1 to BLn. In another embodiment, which is different from that shown, a plurality of strings ST1 to STk may be connected to one of the bit lines BL1 to BLn.

The source line SL may be commonly connected to the strings ST1 to STk. Since the strings ST1 to STk may be configured similarly to each other, the string ST1 connected to the first bit line BL1 will be specifically described as an example.

The string ST1 may include a source select transistor SST, a plurality of memory cells MC1 to MC16, and a drain select transistor DST connected in series between the source line SL and the first bit line BL1. One string ST1 may include at least one or more of the source select transistor SST and the drain select transistor DST, and may include the memory cells MC1 to MC16. The total number of memory cells may be more than the number of memory cells MC1 to MC16 shown in the figure.

A source of the source select transistor SST may be connected to the source line SL and a drain of the drain select transistor DST may be connected to the first bit line BL1. The memory cells MC1 to MC16 may be connected in series between the source select transistor SST and the drain select transistor DST.

Gates of the source select transistors SST included in the different strings ST1 to STk may be connected to the source select line SSL. Gates of the drain select transistors DST included in the different strings ST1 to STk may be connected to the drain select line DSL.

Gates of the memory cells MC1 to MC16 included in the different strings ST1 to STk may be connected to the plurality of word lines WL1 to WL16. A group of memory cells connected to the same word line among memory cells included in the different strings ST1 to STk may be referred to as a physical page PG. Therefore, the physical pages PG of the number of word lines WL1 to WL16 may be included in the memory block BLK1. In FIG. 4, the source line SL, the source select line SSL, the word lines WL1 to WL16, and the drain select line DSL may be included in the row lines RL of FIG. 2.

When one memory cell is a single level cell (SLC) storing one bit of data, one physical page PG may store one logical page (LPG) of data. In addition, one memory cell may store two or more bits of data. In this case, one physical page PG may store two or more logical pages (LPG) of data.

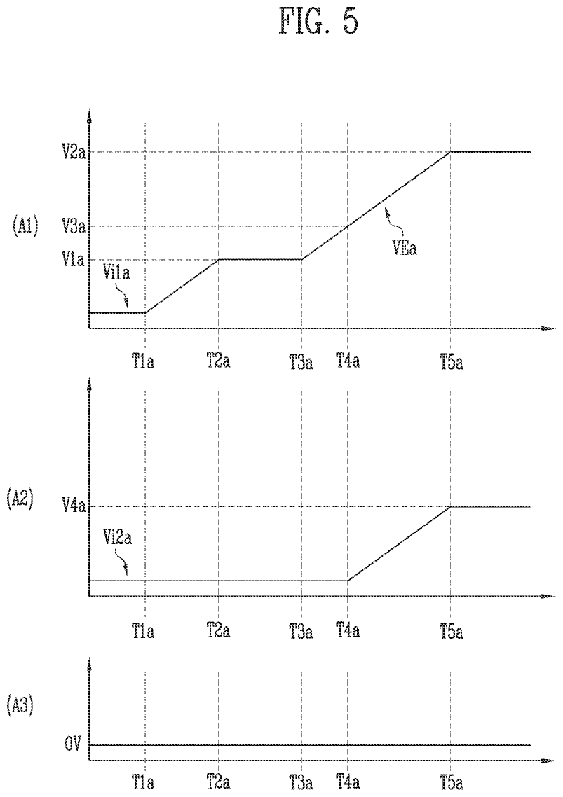

FIG. 5 is a set of diagrams illustrating an erase operation of a memory device according to embodiments of the present disclosure.

In FIG. 5, voltages applied to a conductive line A1, a select line A2, and a word line A3 during the erase operation are shown.

Referring to FIG. 5, the erase operation may include first to fifth time points T1a, T2a, T3a, T4a, and T5a. The first to fifth time points T1a, T2a, T3a, T4a, and T5a may be time points that sequentially occur in the erase operation. The second time point T2a may be a time point later than the first time point T1a, the third time point T3a may be a time point later than the second time point T2a, the fourth time point T4a may be a time point later than the third time point T3a, and the fifth time point T5a may be a time point later than the fourth time point T4a.

In the erase operation, an erase voltage VEa may be applied to the conductive line from the first time point T1a to after the fifth time point T5a. The conductive line may be the bit line or the source line. A time point at which the erase voltage VEa starts to be applied to the conductive line may be defined as the first time point T1a. The erase voltage VEa may be a positive voltage higher than 0 V. Before the erase voltage VEa is applied, a first initial voltage Vi1a may be applied to the conductive line as illustrated in FIG. 5(A1). For example, the first initial voltage Vi1a may be 0 V.

A voltage level of the erase voltage VEa applied to the conductive line may increase from the first time point T1a to the second time point T2a. The erase voltage VEa may increase from the first initial voltage Vi1a to a first voltage level V1a from the first time point T1a to the second time point T2a.

The voltage level of the erase voltage VEa applied to the conductive line may be maintained from the second time point T2a to the third time point T3a. The voltage level of the erase voltage VEa may be maintained as the first voltage level V1a from the second time point T2a to the third time point T3a. A time point at which the voltage level of the erase voltage VEa applied to the conductive line increases and then starts to be maintained may be defined as the second time point T2a.

The voltage level of the erase voltage VEa applied to the conductive line may increase from the third time point T3a to the fifth time point T5a. The voltage level of the erase voltage VEa may increase from the first voltage level V1a to a second voltage level V2a from the third time point T3a to the fifth time point T5a. A time point at which the voltage level of the erase voltage VEa applied to the conductive line is maintained and then starts to increase may be defined as the third time point T3a.

The voltage level of the erase voltage VEa applied to the conductive line may be maintained from the fifth time point T5a. The voltage level of the erase voltage VEa may be maintained as the second voltage level V2a from the fifth time point T5a. The second voltage level V2a may be a maximum erase voltage level. A time point at which the voltage level of the erase voltage VEa applied to the conductive line increases and then starts to be maintained may be defined as the fifth time point T5a.

In the erase operation, a second initial voltage Vi2a may be applied to the select line from before the first time point T1a to the fourth time point T4a as illustrated in FIG. 5(A2). The select line may be the drain select line or the source select line. For example, the second initial voltage Vi2a may be 0 V.

From the fourth time point T4a, the select line may be floated. A time point at which the select line starts to be floated may be defined as the fourth time point T4a. As the select line is floated, a voltage level of the select line may increase by coupling. Since the voltage level of the erase voltage VEa applied to the conductive line increases to the fifth time point T5a, the voltage level of the select line may increase to the fifth time point T5a.

At the fourth time point T4a, the voltage level of the erase voltage VEa may be a third voltage level V3a. From the fifth time point T5a, the voltage level of the select line may be maintained as a fourth voltage level V4a. A difference between the second voltage level V2a and the third voltage level V3a may be the same as the fourth voltage level V4a.

In the erase operation, a voltage of 0 V may be applied to the word line from before the first time point T1a to after the fifth time point T5a as illustrated in FIG. 5(A3).

A gate induced drain leakage (GIDL) may be generated in the string due to a difference between the voltage level of the erase voltage VEa and a voltage level of the second initial voltage Vi2a from the first time point T1a to the fourth time point T4a of the erase operation, and holes generated by the GIDL may be injected into a channel of the string.

When the erase voltage VEa is maintained as the maximum erase voltage level from the fifth time point T5a of the erase operation, the holes injected into the channel of the string may be tunneled, and thus, memory cells of the string may be erased.

Referring to FIGS. 2, 3 and 5, in the erase operation, the control logic 130 may control the peripheral circuit 120 to increase the erase voltage VEa applied to the conductive line from the first time point T1a to the second time point T2a later than the first time point T1a, maintain the erase voltage VEa applied to the conductive line from the second time point T2a to the third time point T3a later than the second time point T2a, increase the erase voltage VEa applied to the conductive line from the third time point T3a to the fifth time point T5a later than the third time point T3a, and float the select line at the fourth time point T4a later than the third time point T3a and earlier than the fifth time point T5a.

In the erase operation, when the erase voltage rapidly increases, a relatively large potential difference may occur between a conductive line adjacent portion and a select line adjacent portion of the channel. A hot carrier may be generated between the conductive line adjacent portion and the select line adjacent portion by the potential difference generated between the conductive line adjacent portion and the select line adjacent portion of the channel, and an electron hole pair may be generated by the hot carrier. The electron of the electron hole pair generated by the hot carrier may be injected into a charge storage layer adjacent to the select line, may change a threshold voltage of the select transistor, and may reduce an on/off characteristic of the select transistor.

In the memory device according to the present disclosure, as the voltage level of the erase voltage VEa is maintained from the second time point T2a to the third time point T3a in the erase operation, a time for the holes of the electron hole pair formed by the GIDL to move to the select line adjacent portion and a word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus, a phenomenon in which the on/off characteristic of the select transistor is reduced due to the hot carrier may be improved.

In the memory device according to the present disclosure, since the select line is floated from the fourth time point T4a between the third time point T3a and the fifth time point T5a, the fourth voltage level V4a of the select line may be sufficiently small after the fifth time point T5a. Accordingly, after the fifth time point T5a, a difference between the voltage level of the select line and the voltage level of the word line may not be large, and the potential difference between the select line adjacent portion and the word line adjacent portion of the channel may be relatively small. Accordingly, a phenomenon may be improved in which the hot carrier is generated in the select line adjacent portion and the word line adjacent portion of the channel after the fifth time point T5a, and thus characteristics of the select transistor and the memory cell are reduced.

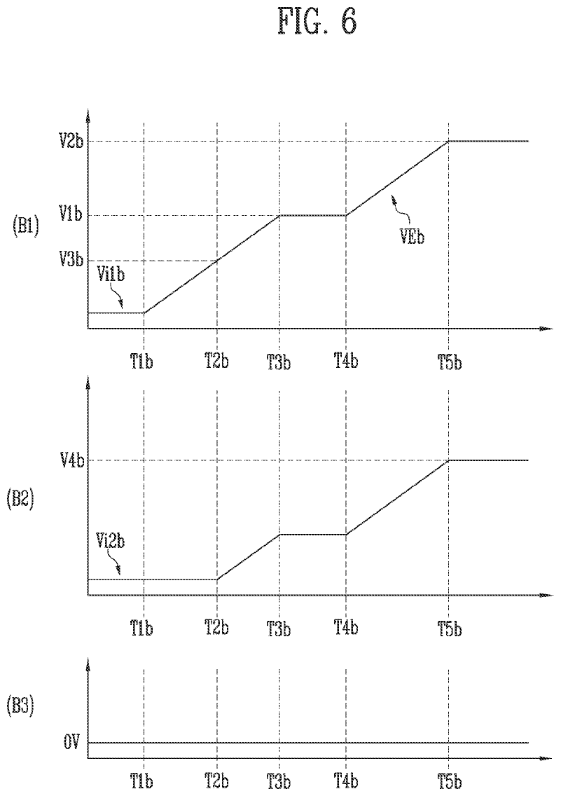

FIG. 6 is a set of diagrams illustrating an erase operation of a memory device according to embodiments of the present disclosure.

In FIG. 6, voltages applied to a conductive line B1, a select line B2, and a word line B3 during the erase operation are shown.

Referring to FIG. 6, the erase operation may include first to fifth time points T1b, T2b, T3b, T4b, and T5b. The first to fifth time points T1b, T2b, T3b, T4b, and T5b may be time points that sequentially occur in the erase operation. The second time point T2b may be a time point later than the first time point T1b, the third time point T3b may be a time point later than the second time point T2b, the fourth time point T4b may be a time point later than the third time point T3b, and the fifth time point T5b may be a time point later than the fourth time point T4b.

In the erase operation, an erase voltage VEb may be applied to the conductive line from the first time point T1b to the fifth time point T5b. The conductive line may be the bit line or the source line. A time point at which the erase voltage VEb starts to be applied to the conductive line may be defined as the first time point T1b. The erase voltage VEb may be a positive voltage higher than 0 V. Before the erase voltage VEb is applied, a first initial voltage Vi1b may be applied to the conductive line as illustrated in FIG. 6(B1). For example, the first initial voltage Vi1b may be 0 V.

A voltage level of the erase voltage VEb applied to the conductive line may increase from the first time point T1b to the third time point T3b. The erase voltage VEb may increase from the first initial voltage Vi1b to the first voltage level V1b from the first time point T1b to the third time point T3b.

The voltage level of the erase voltage VEb applied to the conductive line may be maintained from the third time point T3b to the fourth time point T4b. The voltage level of the erase voltage VEb may be maintained as a first voltage level V1b from the third time point T3b to the fourth time point T4b. A time point at which the voltage level of the erase voltage VEb applied to the conductive line increases and then starts to be maintained may be defined as the third time point T3b.

The voltage level of the erase voltage VEb applied to the conductive line may increase from the fourth time point T4b to the fifth time point T5b. The voltage level of the erase voltage VEb may increase from the first voltage level V1b to a second voltage level V2b from the fourth time point T4b to the fifth time point T5b. A time point at which the voltage level of the erase voltage VEb applied to the conductive line is maintained and then starts to increase may be defined as the fourth time point T4b.

The voltage level of the erase voltage VEb applied to the conductive line may be maintained from the fifth time point T5b. From the fifth time point T5b, the voltage level of the erase voltage VEb may be maintained as the second voltage level V2b. The second voltage level V2b may be a maximum erase voltage level. A time point at which the voltage level of the erase voltage VEb applied to the conductive line increases and then starts to be maintained may be defined as the fifth time point T5b.

In the erase operation, as illustrated in FIG. 6(B2), a second initial voltage Vi2b may be applied to the select line from before the first time point T1b to the second time point T2b. The select line may be the drain select line or the source select line. For example, the second initial voltage Vi2b may be 0 V.

From the second time point T2b, the select line may be floated. A time point at which the select line starts to be floated may be defined as the second time point T2b. As the select line is floated, a voltage level of the select line may increase by coupling. Since the voltage level of the erase voltage VEb applied to the conductive line increases from the second time point T2b to the third time point T3b, is maintained from the third time point T3b to the fourth time point T4b, and increases from the fourth time point T4b to the fifth time point T5b, the voltage level of the select line may increase from the second time point T2b to the third time point T3b, may be maintained from the third time point T3b to the fourth time point T4b, and may increase from the fourth time point T4b to the fifth time point T5b.

At the second time point T2b, the voltage level of the erase voltage VEb may be a third voltage level V3b. From the fifth time point T5b, the voltage level of the select line may be maintained as a fourth voltage level V4b. A difference between the second voltage level V2b and the third voltage level V3b may be the same as the fourth voltage level V4b.

In the erase operation, a voltage of 0 V may be applied to the word line from before the first time point T1b to after the fifth time point T5b as illustrated in FIG. 6(B3).

From the first time point T1b to the second time point T2b of the erase operation, the GIDL may be generated in the string by a difference between the voltage level of the erase voltage VEb and a voltage level of the second initial voltage Vi2b, and holes generated by the GIDL may be injected into the channel of the string.

As the erase voltage VEb is maintained as the maximum erase voltage level from the fifth time point T5b of the erase operation, the holes injected into the channel of the string may be tunneled, and thus the memory cells of the string may be erased.

Referring to FIGS. 2, 3 and 6, in the erase operation, the control logic 130 may control the peripheral circuit 120 to increase the erase voltage VEb applied to the conductive line from the first time point T1b to the third time point T3b later than the first time point T1b, maintain the erase voltage VEb applied to the conductive line from the third time point T3b to the fourth time point T4b later than the third time point T3b, increase the erase voltage VEb applied to the conductive line from the fourth time point T4b to the fifth time point T5b later than the fourth time point T4b, and float the select line at the second time point T2b later than the first time point T1b and earlier than the third time point T3b.

In the memory device according to the present disclosure, as the voltage level of the erase voltage VEb is maintained from the third time point T3b to the fourth time point T4b in the erase operation, the time for the holes of the electron hole pair formed by the GIDL to move to the select line adjacent portion and the word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus the phenomenon may be improved in which the on/off characteristic of the select transistor may be reduced due to the hot carrier.

In the memory device according to the present disclosure, since the select line is floated from the second time point T2b between the first time point T1b and the third time point T3b, the fourth voltage level V4b of the select line may have been sufficiently increased after the fifth time point T5b. Accordingly, after the fifth time point T5b, a difference between the voltage level of the select line and the voltage level of the conductive line may be sufficiently reduced, and the potential difference between the conductive line adjacent portion and the select line adjacent portion of the channel may be relatively small. Accordingly, the phenomenon may be improved in which the hot carrier is generated in the conductive line adjacent portion and the select line adjacent portion of the channel after the fifth time point T5b, and thus the characteristic of the select transistor may be reduced.

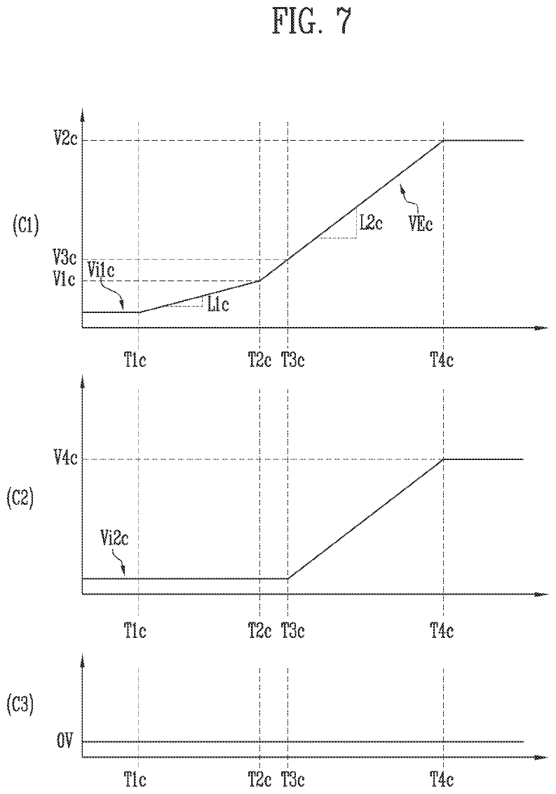

FIG. 7 is a set of diagrams illustrating an erase operation of a memory device according to embodiments of the present disclosure.

In FIG. 7, voltages applied to a conductive line C1, a select line C2, and a word line C3 during the erase operation are shown.

Referring to FIG. 7, the erase operation may include first to fourth time points T1c, T2c, T3c, and T4c. The first to fourth time points T1c, T2c, T3c, and T4c may be time points that sequentially occur in the erase operation. The second time point T2c may be a time point later than the first time point T1c, the third time point T3c may be a time point later than the second time point T2c, and the fourth time point T4c may be a time point later than the third time point T3c.

In the erase operation, an erase voltage VEc may be applied to the conductive line from the first time point T1c to the fourth time point T4c. The conductive line may be the bit line or the source line. A time point at which the erase voltage VEc is applied to the conductive line may be defined as the first time point T1c. The erase voltage VEc may be a positive voltage higher than 0 V. Before the erase voltage VEc is applied, a first initial voltage Vi1c may be applied to the conductive line. For example, the first initial voltage Vi1c may be 0 V.

A voltage level of the erase voltage VEc applied to the conductive line may increase from the first time point T1c to the second time point T2c at a first slope L1c. The erase voltage VEc may increase from the first initial voltage Vi1c to a first voltage level V1c from the first time T1c to the second time T2c as illustrated in FIG. 7(C1).

The voltage level of the erase voltage VEc applied to the conductive line may increase from the second time point T2c to the fourth time point T4c at a second slope L2c. The second slope L2c may be greater than the first slope L1c. The first slope L1c may be gentler than the second slope L2c. A time point at which the slope at which the voltage level of the erase voltage VEc increases is changed may be defined as the second time point T2c. The erase voltage VEc may increase from the first voltage level V1c to a second voltage level V2c from the second time point T2c to the fourth time point T4c.

The voltage level of the erase voltage VEc applied to the conductive line may be maintained from the fourth time point T4c. From the fourth time point T4c, the voltage level of the erase voltage VEc may be maintained as the second voltage level V2c. The second voltage level V2c may be a maximum erase voltage level. A time point at which the voltage level of the erase voltage VEc applied to the conductive line increases and then starts to be maintained may be defined as the fourth time point T4c.

In the erase operation, a second initial voltage Vi2c may be applied to the select line from before the first time point T1c to the third time point T3c as illustrated in FIG. 7(C2). The select line may be the drain select line or the source select line. For example, the second initial voltage Vi2c may be 0 V.

From the third time point T3c, the select line may be floated. A time point at which the select line starts to be floated may be defined as the third time point T3c. As the select line is floated, a voltage level of the select line may increase by coupling. Since the voltage level of the erase voltage VEc applied to the conductive line increases from the third time point T3c to the fourth time point T4c at the second slope L2c, the voltage level of the select line may increase from the third time point T3c to the fourth time point T4c at the second slope L2c.

At the third time point T3c, the voltage level of the erase voltage VEc may be a third voltage level V3c. From the fourth time point T4c, the voltage level of the select line may be maintained as a fourth voltage level V4c. A difference between the second voltage level V2c and the third voltage level V3c may be the same as the fourth voltage level V4c.

In the erase operation, as illustrated in FIG. 7(C3), a voltage of 0 V may be applied to the word line from before the first time point T1c to after the fourth time point T4c.

From the first time point T1c to the third time point T3c of the erase operation, the GIDL may be generated in the string by a difference between the voltage level of the erase voltage VEc and a voltage level of the second initial voltage Vi2c, and holes generated by the GIDL may be injected into the channel of the string.

As the erase voltage VEc is maintained as the maximum erase voltage level from the fourth time point T4c of the erase operation, the holes injected into the channel of the string may be tunneled, and thus the memory cells of the string may be erased.

Referring to FIGS. 2, 3 and 7, in the erase operation, the control logic 130 may control the peripheral circuit 120 to increase the erase voltage VEc applied to the conductive line from the first time point T1c to the second time point T2c later than the first time point T1c at the first slope L1c, increase the erase voltage VEc applied to the conductive line from the second time point T2c to the fourth time point T4c later than the second time point T2c at the second slope L2c greater than the first slope L1c, and float the select line at the third time point T3c later than the second time point T2c and earlier than the fourth time point T4c.

In the memory device according to the present disclosure, the voltage level of the erase voltage VEc may relatively gently increase from the first time point T1c to the second time point T2c in the erase operation. Accordingly, the time for the holes of the electron hole pair formed by the GIDL to move to the select line adjacent portion and the word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus the phenomenon in which the on/off characteristic of the select transistor is reduced due to the hot carrier may be improved.

In the memory device according to the present disclosure, since the select line is floated from the third time point T3c between the second time point T2c and the fourth time point T4c, the fourth voltage level V4c of the select line may be sufficiently small after the fourth time point T4c. Accordingly, after the fourth time point T4c, a difference between the voltage level of the select line and the voltage level of the word line may not be large, and the potential difference between the select line adjacent portion and the word line adjacent portion of the channel may be relatively small. Accordingly, the phenomenon may be improved in which the hot carrier is generated in the select line adjacent portion and the word line adjacent portion of the channel after the fourth time point T4c, and thus, the characteristics of the select transistor and the memory cell may be reduced.

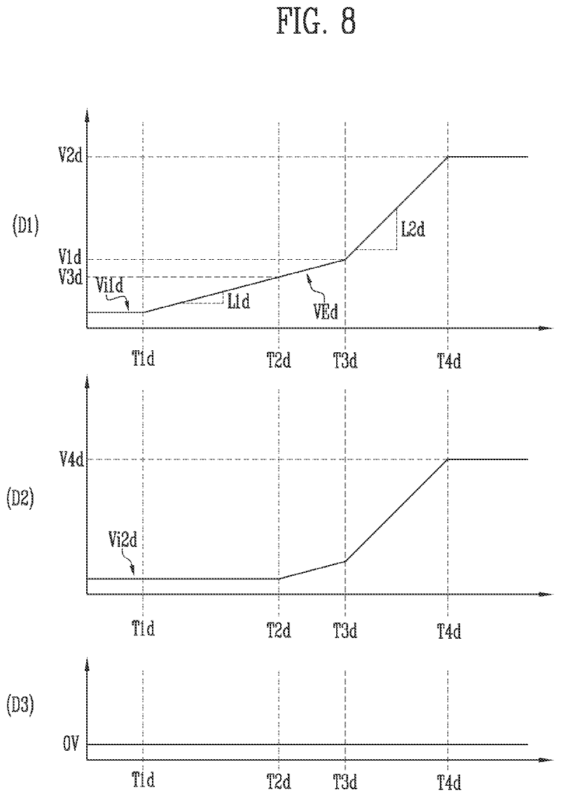

FIG. 8 is a diagram illustrating an erase operation of a memory device according to embodiments of the present disclosure.

In FIG. 8, voltages applied to a conductive line D1, a select line D2, and a word line D3 during the erase operation are shown.

Referring to FIG. 8, the erase operation may include first to fourth time points T1d, T2d, T3d, and T4d. The first to fourth time points T1d, T2d, T3d, and T4d may be time points that sequentially occur in the erase operation. The second time point T2d may be a time point later than the first time point T1d, the third time point T3d may be a time point later than the second time point T2d, and the fourth time point T4d may be a time point later than the third time point T3d.

In the erase operation, an erase voltage VEd may be applied to the conductive line from the first time point T1d to the fourth time point T4d. The conductive line may be the bit line or the source line. A time point at which the erase voltage VEd is applied to the conductive line may be defined as the first time point T1d. The erase voltage VEd may be a positive voltage higher than 0 V. Before the erase voltage VEd is applied, a first initial voltage Vi1d may be applied to the conductive line as illustrated in FIG. 8(D1). For example, the first initial voltage Vi1d may be 0 V.

A voltage level of the erase voltage VEd applied to the conductive line may increase from the first time point T1d to the third time point T3d at a first slope L1d. The erase voltage VEd may increase from the first initial voltage Vi1d to a first voltage level V1d from the first time point T1d to the third time point T3d.

The voltage level of the erase voltage VEd applied to the conductive line may increase from the third time point T3d to the fourth time point T4d at a second slope L2d. The second slope L2d may be greater than the first slope L1d. The first slope L1d may be gentler than the second slope L2d. A time point at which the slope at which the voltage level of the erase voltage VEd increases is changed may be defined as the third time point T3d. The erase voltage VEd may increase from the first voltage level V1d to a second voltage level V2d from the third time point T3d to the fourth time point T4d.

The voltage level of the erase voltage VEd applied to the conductive line may be maintained from the fourth time point T4d. From the fourth time point T4d, the voltage level of the erase voltage VEd may be maintained as the second voltage level V2d. The second voltage level V2d may be a maximum erase voltage level. A time point at which the voltage level of the erase voltage VEd applied to the conductive line increases and then starts to be maintained may be defined as the fourth time point T4d.

In the erase operation, a second initial voltage Vi2d may be applied to the select line from before the first time point T1d to the second time point T2d as illustrated in FIG. 8(D2). The select line may be the drain select line or the source select line. For example, the second initial voltage Vi2d may be 0 V.

From the second time point T2d, the select line may be floated. A time point at which the select line starts to be floated may be defined as the second time point T2d. As the select line is floated, a voltage level of the select line may increase by coupling. Since the voltage level of the erase voltage VEd applied to the conductive line increases from the second time point T2d to the third time point T3d at the first slope L1d and increases from the third time point T3d to the fourth time point T4d at the second slope L2d, the voltage level of the select line may increase from the second time point T2d to the third time point T3d at the first slope L1d and increase from the third time point T3d to the fourth time point T4d at the second slope L2d.

At the second time point T2d, the voltage level of the erase voltage VEd may be a third voltage level V3d. From the fourth time point T4d, the voltage level of the select line may be maintained as a fourth voltage level V4d. A difference between the second voltage level V2d and the third voltage level V3d may be the same as the fourth voltage level V4d.

In the erase operation, a voltage of 0 V may be applied to the word line from before the first time point T1d to after the fourth time point T4d as illustrated in FIG. 8(D3).

From the first time point T1d to the second time point T2d of the erase operation, the GIDL may be generated in the string by the difference between the voltage level of the erase voltage VEd and a voltage level of the second initial voltage Vi2d, and the holes generated by the GIDL may be injected into the channel of the string.

When the erase voltage VEd is maintained as the maximum erase voltage level from the fourth time point T4d of the erase operation, the holes injected into the channel of the string may be tunneled, and thus the memory cells of the string may be erased.

Referring to FIGS. 2, 3 and 8, in the erase operation, the control logic 130 may control the peripheral circuit 120 to increase the erase voltage VEd applied to the conductive line from the first time point T1d to the third time point T3d later than the first time point T1d at the first slope L1d, increase the erase voltage VEd applied to the conductive line from the third time point T3d to the fourth time point T4d later than the third time point T3d at the second slope L2d greater than the first slope L1d, and float the select line at the second time point T2d later than the first time point T1d and earlier than the third time point T3d.

In the memory device according to the present disclosure, the voltage level of the erase voltage VEd may relatively gently increase from the first time point T1d to the third time point T3d in the erase operation. Accordingly, the time for the holes of the electron hole pair formed by the GIDL to move to the select line adjacent portion and the word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus, the phenomenon may be improved in which the on/off characteristic of the select transistor is reduced due to the hot carrier.

In the memory device according to the present disclosure, since the select line is floated from the second time point T2d between the first time point T1d and the third time point T3d, the fourth voltage level V4d of the select line may be sufficiently increased after the fourth time point T4d. Accordingly, after the fourth time point T4d, a difference between the voltage level of the select line and the voltage level of the conductive line may be reduced, and the potential difference between the conductive line adjacent portion and the select line adjacent portion of the channel may be relatively small. Accordingly, the phenomenon may be improved in which the hot carrier is generated in the conductive line adjacent portion and the select line adjacent portion of the channel after the fourth time point T4d and thus the characteristic of the select transistor is reduced.

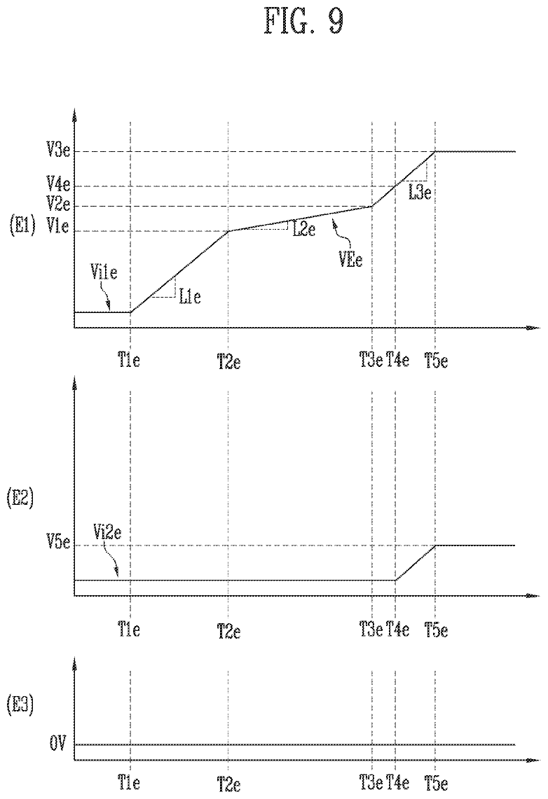

FIG. 9 is a set of diagrams illustrating an erase operation of a memory device according to embodiments of the present disclosure.

In FIG. 9, voltages applied to a conductive line E1, a select line E2, and a word line E3 during the erase operation are shown.

Referring to FIG. 9, the erase operation may include first to fifth time points T1e, T2e, T3e, T4e, and T5e. The first to fifth time points T1e, T2e, T3e, T4e, and T5e may be time points that sequentially occur in the erase operation. The second time point T2e may be a time point later than the first time point T1e, the third time point T3e may be a time point later than the second time point T2e, the fourth time point T4e may be a time point later than the third time point T3e, and the fifth time point T5e may be a time point later than the fourth time point T4e.

In the erase operation, an erase voltage VEe may be applied to the conductive line from the first time point T1e to after the fifth time point T5e. The conductive line may be the bit line or the source line. A time point at which the erase voltage VEe is applied to the conductive line may be defined as the first time point T1e. The erase voltage VEe may be a positive voltage higher than 0 V. Before the erase voltage VEe is applied, a first initial voltage Vi1e may be applied to the conductive line as illustrated in FIG. 9(E1). For example, the first initial voltage Vi1e may be 0 V.

A voltage level of the erase voltage VEe applied to the conductive line may increase from the first time point T1e to the second time point T2e at a first slope L1e. The erase voltage VEe may increase from the first initial voltage VI1e to a first voltage level V1e from the first time point T1e to the second time point T2e as illustrated in FIG. 9(E1).

The voltage level of the erase voltage VEe applied to the conductive line may increase from the second time point T2e to the third time point T3e at a second slope L2e. The second slope L2e may be less than the first slope L1e. The second slope L2e may be gentler than the first slope L1e. The voltage level of the erase voltage VEe may increase from the first voltage level V1e to a second voltage level V2e from the second time point T2e to the third time point T3e. A time point at which a slope at which the voltage level of the erase voltage VEe applied to the conductive line increases is changed from the first slope L1e to the second slope L2e may be defined as the second time point T2e.

The voltage level of the erase voltage VEe applied to the conductive line may increase from the third time point T3e to the fifth time point T5e at a third slope L3e. The third slope L3e may be greater than the second slope L2e. The second slope L2e may be gentler than the third slope L3e. The third slope L3e may be the same as the first slope L1e, or may be greater than the first slope L1e. The voltage level of the erase voltage VEe may increase from the second voltage level V2e to a third voltage level V3e from the third time point T3e to the fifth time point T5e. A time point at which the slope at which the voltage level of the erase voltage VEe applied to the conductive line increases is changed from the second slope L2e to the third slope L3e may be defined as the third time point T3e.

The voltage level of the erase voltage VEe applied to the conductive line may be maintained from the fifth time point T5e. From the fifth time point T5e, the voltage level of the erase voltage VEe may be maintained as the third voltage level V3e. The third voltage level V3e may be a maximum erase voltage level. A time point at which the voltage level of the erase voltage VEe applied to the conductive line increases at the third slope L3e and then starts to be maintained may be defined as the fifth time point T5e.

In the erase operation, a second initial voltage Vi2e may be applied to the select line from before the first time point T1e to the fourth time point T4e as illustrated in FIG. 9(E2). The select line may be the drain select line or the source select line. For example, the second initial voltage Vi2e may be 0 V.

From the fourth time point T4e, the select line may be floated. A time point at which the select line starts to be floated may be defined as the fourth time point T4e. As the select line is floated, a voltage level of the select line may increase by coupling. Since the voltage level of the erase voltage VEe applied to the conductive line increases from the fourth time point T4e to the fifth time point T5e at the third slope L3e, the voltage level of the selected line may increase from the fourth time point T4e to the fifth time point T5e at the third slope L3e.

At the fourth time point T4e, the voltage level of the erase voltage VEe may be a fourth voltage level V4e. From the fifth time point T5e, the voltage level of the select line may be maintained as a fifth voltage level V5e. A difference between the third voltage level V3e and the fourth voltage level V4e may be the same as the fifth voltage level V5e.

In the erase operation, a voltage of 0 V may be applied to the word line from before the first time point T1e to after the fifth time point T5e as illustrated in FIG. 9(E3).

From the first time point T1e to the fourth time point T4e of the erase operation, the GIDL may be generated in the string by the difference between the voltage level of the erase voltage VEe and a voltage level of the second initial voltage Vi2e, and the holes generated by the GIDL may be injected into the channel of the string.

When the erase voltage VEe is maintained as the maximum erase voltage level from the fifth time point T5e of the erase operation, the holes injected into the channel of the string may be tunneled, and thus the memory cells of the string may be erased.

Referring to FIGS. 2, 3 and 9, in the erase operation, the control logic 130 may control the peripheral circuit 120 to increase the erase voltage VEe applied to the conductive line from the first time point T1e to the second time point T2e later than the first time point T1e at the first slope L1e, increase the erase voltage VEe applied to the conductive line from the second time point T2e to the third time point T3e later than the second time point T2e at the second slope L2e less than the first slope L1e, increase the erase voltage VEe applied to the conductive line from the third time point T3e to the fifth time point T5e later than the third time point T3e at the third slope L3e greater than the second slope L2e, and float the select line at the fourth time point T4e later than the third time point T3e and earlier than the fifth time point T5e.

In the memory device according to the present disclosure, the voltage level of the erase voltage VEe may relatively gently increase from the second time point T2e to the third time point T3e in the erase operation. Accordingly, the time for the holes of the electron hole pair formed by the GIDL to move to the select line adjacent portion and the word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus the phenomenon may be improved in which the on/off characteristic of the select transistor is reduced due to the hot carrier.

In the memory device according to the present disclosure, since the select line is floated from the fourth time point T4e between the third time point T3e and the fifth time point T5e, the fifth voltage level V5e of the select line may be sufficiently reduced after the fifth time point T5e. Accordingly, after the fifth time point T5e, a difference between the voltage level of the select line and the voltage level of the word line may be reduced, and the potential difference between the select line adjacent portion and the word line adjacent portion of the channel may be relatively small. Accordingly, the phenomenon may be improved in which the hot carrier is generated in the select line adjacent portion and the word line adjacent portion of the channel after the fifth time point T5e, and thus, the characteristics of the select transistor and the memory cell are reduced.

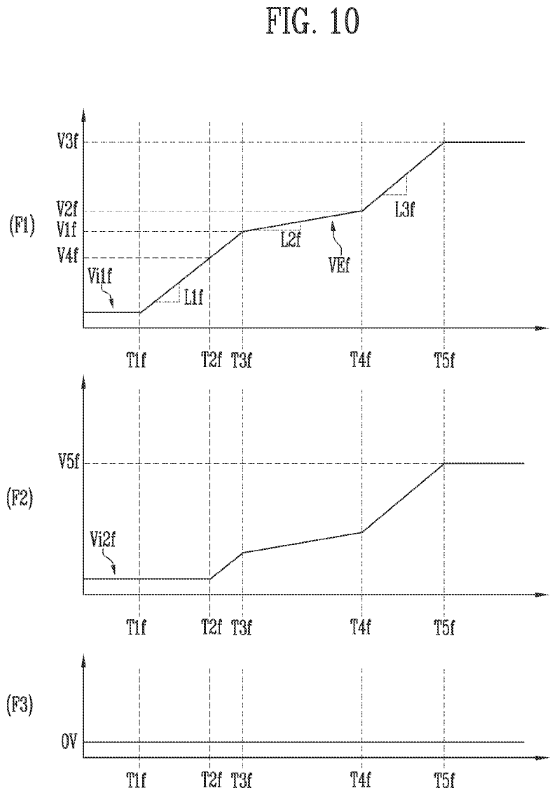

FIG. 10 is a set of diagrams illustrating an erase operation of a memory device according to embodiments of the present disclosure.

In FIG. 10, voltages applied to a conductive line F1, a select line F2, and a word line F3 during the erase operation are shown.

Referring to FIG. 10, the erase operation may include first to fifth time points T1f, T2f, T3f, T4f, and T5f. The first to fifth time points T1f, T2f, T3f, T4f, and T5f may be time points that sequentially occur in the erase operation. The second time point T2f may be a time point later than the first time point T1f, the third time point T3f may be a time point later than the second time point T2f, the fourth time point T4f may be a time point later than the third time point T3f, and the fifth time point T5f may be a time point later than the fourth time point T4f.

In the erase operation, an erase voltage VEf may be applied to the conductive line from the first time point T1f to the fifth time point T5f. The conductive line may be the bit line or the source line. A time point at which the erase voltage VEf is applied to the conductive line may be defined as the first time point T1f. The erase voltage VEf may be a positive voltage higher than 0 V. Before the erase voltage VEf is applied, a first initial voltage Vi1f may be applied to the conductive line as illustrated in FIG. 10(F1). For example, the first initial voltage Vi1f may be 0 V.

A voltage level of the erase voltage VEf applied to the conductive line may increase from the first time point T1f to the third time point T3f at a first slope L1f. The erase voltage VEf may increase from the first initial voltage Vi1f to a first voltage level V1f from the first time point T1f to the third time point T3f.

The voltage level of the erase voltage VEf applied to the conductive line may increase from the third time point T3f to the fourth time point T4f at a second slope L2f. The second slope L2f may be less than the first slope L1f. The second slope L2f may be gentler than the first slope L1f. The voltage level of the erase voltage VEf may increase from the first voltage level V1f to a second voltage level V2f from the third time point T3f to the fourth time point T4f. A time point at which a slope at which the voltage level of the erase voltage VEf applied to the conductive line increases is changed from the first slope L1f to the second slope L2f may be defined as the third time point T3f.

The voltage level of the erase voltage VEf applied to the conductive line may increase from the fourth time point T4f to the fifth time point T5f at a third slope L3f. The third slope L3f may be greater than the second slope L2f. The second slope L2f may be gentler than the third slope L3f. The third slope L3f may be the same as the first slope L1f, or may be greater than the first slope L1f. The voltage level of the erase voltage VEf may increase from the second voltage level V2f to a third voltage level V3f from the fourth time point T4f to the fifth time point T5f. A time point at which the slope at which the voltage level of the erase voltage VEf applied to the conductive line increases is changed from the second slope L2f to the third slope L3f may be defined as the fourth time point T4f.

The voltage level of the erase voltage VEf applied to the conductive line may be maintained from the fifth time point T5f. From the fifth time point T5f, the voltage level of the erase voltage VEf may be maintained as the third voltage level V3f. The third voltage level V3f may be a maximum erase voltage level. A time point at which the voltage level of the erase voltage VEf applied to the conductive line increases at the third slope L3f and then starts to be maintained may be defined as the fifth time point T5f.

In the erase operation, a second initial voltage Vi2f may be applied to the select line from before the first time point T1f to the second time point T2f as illustrated in FIG. 10(F2). The select line may be the drain select line or the source select line. For example, the second initial voltage Vi2f may be 0 V.

From the second time point T2f, the select line may be floated. A time point at which the select line starts to be floated may be defined as the second time point T2f. As the select line is floated, a voltage level of the select line may increase by coupling. Since the voltage level of the erase voltage VEf applied to the conductive line increases from the second time point T2f to the third time point T3f at the first slope L1f, increases from the third time point T3f to the fourth time point T4f at the second slope L2f, and increases from the fourth time point T4f to the fifth time point T5f at the third slope L3f, the voltage level of the select line may increase from the second time point T2f to the third time point T3f at the first slope L1f, increase from the third time point T3f to the fourth time point T4f at the second slope L2f, and increase from the fourth time point T4f to the fifth time point T5f at the third slope L3f.

At the second time point T2f, the voltage level of the erase voltage VEf may be a fourth voltage level V4f. From the fifth time point T5f, the voltage level of the select line may be maintained as the fifth voltage level V5f. A difference between the third voltage level V3f and the fourth voltage level V4f may be the same as the fifth voltage level V5f.

In the erase operation, a voltage of 0 V may be applied to the word line from before the first time point T1f to after the fifth time point T5f as illustrated in FIG. 10(F3).

From the first time point T1f to the second time point T2f of the erase operation, the GIDL may be generated in the string by a difference between the voltage level of the erase voltage VEf and a voltage level of the second initial voltage Vi2f, and the holes generated by the GIDL may be injected into the channel of the string.

When the erase voltage VEf is maintained as the maximum erase voltage level from the fifth time point T5f of the erase operation, the holes injected into the channel of the string may be tunneled, and thus the memory cells of the string may be erased.

Referring to FIGS. 2, 3 and 10, in the erase operation, the control logic 130 may control the peripheral circuit 120 to increase the erase voltage VEf applied to the conductive line from the first time point T1f to the third time point T3f later than the first time point T1f at the first slope L1f, increase the erase voltage VEf applied to the conductive line from the third time point T3f to the fourth time point T4f later than the third time point T3f at the second slope L2f less than the first slope L1f, increase the erase voltage VEf applied to the conductive line from the fourth time point T4f to the fifth time point T5f later than the fourth time point T4f at the third slope L3f greater than the second slope L2f, and float the select line at the second time point T2f later than the first time point T1f and earlier than the third time point T3f.

In the memory device according to the present disclosure, the voltage level of the erase voltage VEf may relatively gently increase from the third time point T3f to the fourth time point T4f in the erase operation. Accordingly, the time for the holes of the electron hole pair formed by the GIDL to move to the select line adjacent portion and the word line adjacent portion of the channel may be secured. As the holes move to the select line adjacent portion and the word line adjacent portion of the channel, the potential difference between the conductive line adjacent portion and the select line adjacent portion of the channel may be relatively reduced, and thus the phenomenon may be improved in which the on/off characteristic of the select transistor is reduced due to the hot carrier.

In the memory device according to the present disclosure, since the select line is floated from the second time point T2f between the first time point T1f and the third time point T3f, the fifth voltage level V5f of the select line may be sufficiently increased after the fifth time point T5f. Accordingly, after the fifth time point T5f, a difference between the voltage level of the select line and the voltage level of the conductive line may be reduced, and the potential difference between the conductive line adjacent portion and the select line adjacent portion of the channel may be relatively small. Accordingly, the phenomenon may be improved in which the hot carrier is generated in the conductive line adjacent portion and the select line adjacent portion of the channel after the fifth time point T5f, and thus, the on/off characteristic of the select transistor is reduced.

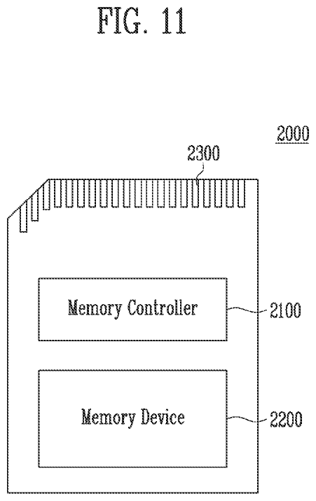

FIG. 11 is a block diagram illustrating a memory card system to apply to the storage device according to an embodiment of the present disclosure.

Referring to FIG. 11, the memory card system 2000 includes a memory controller 2100, a memory device 2200, and a connector 2300.

The memory controller 2100 may be connected to the memory device 2200. The memory controller 2100 may be configured to access the memory device 2200. For example, the memory controller 2100 may be configured to perform a read operation, a program operation, and an erase operation or control a background operation of the memory device 2200. The memory controller 2100 is configured to provide an interface between the memory device 2200 and a host. The memory controller 2100 is configured to drive firmware that controls the memory device 2200. The memory controller 2100 may be implemented in a same manner as the memory controller 200 described with reference to FIG. 1.

For example, the memory controller 2100 may include components such as a random access memory (RAM), a processor, a host interface, a memory interface, and an error corrector.

The memory controller 2100 may communicate with an external device through the connector 2300. The memory controller 2100 may communicate with an external device (for example, the host) according to a specific communication standard. For example, the memory controller 2100 may be configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 2300 may be defined by at least one of the various communication standards described above.

For example, the memory device 2200 may be implemented with various non-volatile memory elements such as an electrically erasable and programmable ROM (EEPROM), a NAND flash memory, a NOR flash memory, a phase-change RAM (PRAM), a resistive RAM (ReRAM), a ferroelectric RAM (FRAM), and a spin transfer torque magnetic RAM (STT-MRAM).

For example, the memory controller 2100 or the memory device 2200 may be packaged and provided as one semiconductor package in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline (SOIC), a shrink small outline package (SSOP), a thin small outline (TSOP), a system in package (SIP), a multi-chip package (MCP), a wafer-level fabricated package (WFP), or a wafer-level processed stack package (WSP). Alternatively, the memory device 2200 may include a plurality of non-volatile memory chips, and the plurality of non-volatile memory chips may be packaged and provided as one semiconductor package based on the above-described package methods.

For example, the memory controller 2100 and the memory device 2200 may be integrated into one semiconductor device. For example, the memory controller 2100 and the memory device 2200 may be integrated into one semiconductor device to configure a solid state drive (SSD). The memory controller 2100 and the memory device 2200 may be integrated into one semiconductor device to configure a memory card. For example, the memory controller 2100 and the memory device 2200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

For example, the memory device 2200 may be the memory device 100 described with reference to FIG. 1.

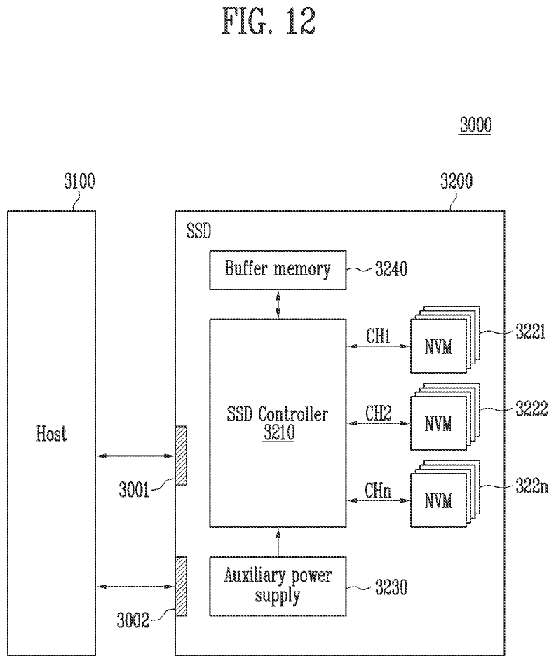

FIG. 12 is a block diagram illustrating a solid state drive (SSD) system for application of the storage device according to an embodiment of the present disclosure.

Referring to FIG. 12, the SSD system 3000 includes a host 3100 and an SSD 3200. The SSD 3200 may exchange a signal SIG with the host 3100 through a signal connector 3001 and may receive power PWR through a power connector 3002. The SSD 3200 may include an SSD controller 3210, a plurality of flash memories 3221 to 322n, an auxiliary power device 3230, and a buffer memory 3240.

In an embodiment, the SSD controller 3210 may perform the function of the memory controller 200 described with reference to FIG. 1.

The SSD controller 3210 may control the plurality of flash memories 3221 to 322n in response to the signal SIG received from the host 3100. For example, the signal SIG may be signals based on an interface between the host 3100 and the SSD 3200. For example, the signal SIG may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power device 3230 may be connected to the host 3100 through the power connector 3002. The auxiliary power device 3230 may receive the power PWR from the host 3100 and may charge the power. The auxiliary power device 3230 may provide power to the SSD 3200 when a power supply from the host 3100 is not evenly provided. For example, the auxiliary power device 3230 may be positioned in the SSD 3200 or may be positioned outside the SSD 3200. For example, the auxiliary power device 3230 may be positioned on a main board and may provide auxiliary power to the SSD 3200.

The buffer memory 3240 operates as a buffer memory of the SSD 3200. For example, the buffer memory 3240 may temporarily store data received from the host 3100 or data received from the plurality of flash memories 3221 to 322n, or may temporarily store metadata (for example, a mapping table) of the flash memories 3221 to 322n. The buffer memory 3240 may include a volatile memory such as a DRAM, an SDRAM, a DDR SDRAM, an LPDDR SDRAM, and a GRAM, or a non-volatile memory such as an FRAM, a ReRAM, an STT-MRAM, and a PRAM.

For example, the non-volatile memories 3321 to 322n may be the memory device 100 described with reference to FIG. 1.

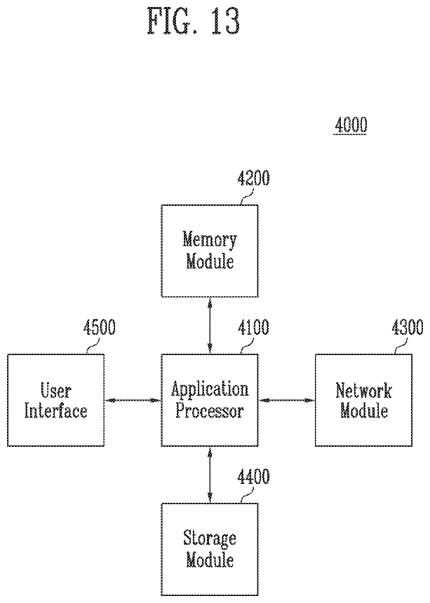

FIG. 13 is a block diagram illustrating a user system for application of the storage device according to an embodiment of the present disclosure.

Referring to FIG. 13, the user system 4000 may include an application processor 4100, a memory module 4200, a network module 4300, a storage module 4400, and a user interface 4500.

The application processor 4100 may drive components, an operating system (OS), a user program, or the like included in the user system 4000. For example, the application processor 4100 may include controllers, interfaces, graphics engines, and the like that control the components included in the user system 4000. The application processor 4100 may be provided as a system-on-chip (SoC).

The memory module 4200 may operate as a main memory, an operation memory, a buffer memory, or a cache memory of the user system 4000. The memory module 4200 may include a volatile random access memory such as a DRAM, an SDRAM, a DDR SDRAM, a DDR2 SDRAM, a DDR3 SDRAM, an LPDDR SDARM, an LPDDR2 SDRAM, and an LPDDR3 SDRAM, or a non-volatile random access memory, such as a PRAM, a ReRAM, an MRAM, and an FRAM. For example, the application processor 4100 and memory module 4200 may be packaged based on a package on package (POP) and provided as one semiconductor package.

The network module 4300 may communicate with external devices. For example, the network module 4300 may support wireless communication such as code division multiple access (CDMA), global system for mobile communications (GSM), wideband CDMA (WCDMA), CDMA-2000, time division multiple access (TDMA), long term evolution, Wimax, WLAN, UWB, Bluetooth, and WI-FI. For example, the network module 4300 may be included in the application processor 4100.

The storage module 4400 may store data. For example, the storage module 4400 may store data received from the application processor 4100. Alternatively, the storage module 4400 may transmit data stored in the storage module 4400 to the application processor 4100. For example, the storage module 4400 may be implemented with a non-volatile semiconductor memory element such as a phase-change RAM (PRAM), a magnetic RAM (MRAM), a resistive RAM (RRAM), a NAND flash, a NOR flash, and a three-dimensional NAND flash. For example, the storage module 4400 may be provided as a removable storage device (removable drive), such as a memory card, and an external drive of the user system 4000.

For example, the storage module 4400 may include a plurality of non-volatile memory devices, and the plurality of non-volatile memory devices may be the memory device 100 described with reference to FIG. 1.

The user interface 4500 may include interfaces for inputting data or an instruction to the application processor 4100 or for outputting data to an external device. For example, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may include user output interfaces such as a liquid crystal display (LCD), an organic light emitting diode (OLED) display device, an active matrix OLED (AMOLED) display device, an LED, a speaker, and a monitor.

What is claimed is:

1. A memory device comprising:
a string including a plurality of memory cells and a select transistor connected between a conductive line and the plurality of memory cells;
a peripheral circuit configured to perform an erase operation of the string; and
a control logic configured to control the peripheral circuit to increase a voltage level of an erase voltage applied to the conductive line for a first time period that includes time one to later time two, maintain the voltage level applied as the erase voltage for a second time period that includes time two to later time three, increase the voltage level of the erase voltage applied for a third time period that includes time three to later time four, and float a select line connected to the select transistor for a fourth time period located between time one and later time two, or for a fifth time period located between time three and later time four, during the erase operation.

2. The memory device of claim 1, wherein the control logic controls the peripheral circuit to float the select line at a beginning of the fourth time period.

3. The memory device of claim 2, wherein the control logic controls the peripheral circuit to apply an initial voltage to the select line from time one to the beginning of the fourth time period.

4. The memory device of claim 3, wherein the initial voltage is 0 V.

5. The memory device of claim 1, wherein the control logic controls the peripheral circuit to float the select line at a beginning of the fifth time period.

6. The memory device of claim 1, wherein the control logic controls the peripheral circuit so that a voltage of 0 V is applied to word lines connected to the memory cells from the time one to the time four.

7. The memory device of claim 1, wherein the conductive line is a source line, and
the select line is a source select line.

8. A memory device comprising:
a string including a plurality of memory cells and a select transistor connected between a conductive line and the plurality of memory cells;
a peripheral circuit configured to perform an erase operation of the string; and
a control logic configured to control the peripheral circuit to increase a voltage level of an erase voltage applied to the conductive line for a first time period from time one to later time two at a first voltage-time slope, and increase the voltage level of the erase voltage for a second time period from time two to later time three at a second voltage-time slope, during the erase operation,
wherein the second voltage-time slope is greater than the first voltage-time slope.

9. The memory device of claim 8, wherein the control logic controls the peripheral circuit to float a select line connected to the select transistor at a time four later than the time one and earlier than the time two.

10. The memory device of claim 9, wherein the control logic controls the peripheral circuit to apply an initial voltage to the select line from the time one to the time four.

11. The memory device of claim 8, wherein the control logic controls the peripheral circuit to float a select line connected to the select transistor at a time five later than the time two and earlier than the time three.

12. The memory device of claim 11, wherein the control logic controls the peripheral circuit to apply an initial voltage to the select line from the time one to the time five.

13. The memory device of claim 8, wherein the conductive line is a source line.

14. The memory device of claim 8, wherein the conductive line is a bit line.

15. A memory device comprising:
a string including a plurality of memory cells and a select transistor connected between a conductive line and the plurality of memory cells;
a peripheral circuit configured to perform an erase operation of the string; and
a control logic configured to control the peripheral circuit to increase a voltage level of an erase voltage applied to the conductive line for a first time period for a time one to a later time two at a first voltage-time slope, increase the voltage level of the erase voltage for a second time period from time two to a later time three at a second voltage-time slope, and increase the voltage level of the erase voltage from the time three to later time four at a third voltage-time slope, during the erase operation,
wherein each of the first voltage-time slope and the third voltage-time slope is greater than the second voltage-time slope.

16. The memory device of claim 15, wherein the control logic controls the peripheral circuit to float a select line connected to the select transistor at a time five later than the time one and earlier than the time two.

17. The memory device of claim 16, wherein the voltage level of the select line increases at the first voltage-time slope from the time five to the time two, increases at the second voltage-time slope from the time two to the time three, and increases at the third voltage-time slope from the time three to the time four.

18. The memory device of claim 15, wherein the control logic controls the peripheral circuit to float a select line connected to the select transistor at a time six later than the time three and earlier than the time four.

19. The memory device of claim 15, wherein the third voltage-time slope is greater than the first voltage-time slope.

20. The memory device of claim 15, wherein the third voltage-time slope is the same as the first voltage-time slope.
